(19) United States
(12) Patent Application Publication
(10) Pub. No.: US 2010/0096169 A1
(43) Pub. Date: Apr. 22, 2010

(54) Polyamide Resin as Well as Epoxy Resin Composition Using the Same and Use Thereof

(75) Inventors: Ryutaro Tanaka, Tokyo (JP); Makoto Uchida, Tokyo (JP); Mitsuyo Nishitoh, Tokyo (JP)

Correspondence Address: PETERS VERNY , L.L.P., 425 SHERMAN AVENUE, SUITE 230, PALO ALTO, CA, 94306, US

(73) Assignee: NIPPONKAYAKU KABUSHIKIKAISHA, Tokyo (JP)

(21) Appl. No.: 12/516,971

(22) PCT Filed: Dec. 11, 2007
(86) PCT No.: PCT/JP2007/073869

§ 371 Date: May 29, 2009

(30) Foreign Application Priority Data
Dec. 13, 2006 (JP) 2006/336193

(51) Int. Cl. H05K 1/03; C08L 77/00; B32B 27/38

(52) U.S. Cl. 174/255; 525/421; 428/418

(57) ABSTRACT

The invention provides a phenolic hydroxyl group-containing rubber-modified polyamide resin capable of providing a cured product with excellent heat resistance, adhesion properties, electrically insulating property and flame retardance and having a sufficient flexibility when being shaped into a film, which is characterized by having in its molecule (a) a phenolic hydroxyl group-containing aromatic polyamide segment represented by the following formula (1):

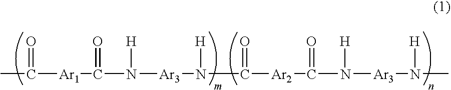

(in the formula (1), m and n are average values and satisfy a relationship of 0.005≦n/(m+n)≦1.00 and m+n is an integer of 2-200, and Ar₁ is a bivalent aromatic group, Ar₂ is a bivalent aromatic group having a phenolic hydroxyl group and Ar₃ is a bivalent aromatic group) and (b) a hydrogenated butadiene polymer segment.

### TECHNICAL FIELD

This invention relates to a phenolic hydroxyl group-containing rubber-modified polyamide resin capable of providing a cured product with excellent heat resistance, adhesion properties, electrically insulating property and flame retardance and having a sufficient flexibility when being shaped into a film and an epoxy resin composition containing the phenolic hydroxyl group-containing rubber-modified polyamide resin and an epoxy resin as an essential component as well as a flexible wiring board using the same and constructional member thereof and an interlaminar insulating film.

### RELATED ART

Heretofore, bisphenol A-type epoxy resin has been mentioned as an epoxy resin most commonly used in an epoxy resin composition. Also, an acid anhydride or an amine-based compound is known as a curing agent for the epoxy resin, but a phenol novolac being excellent in the electric reliability from a viewpoint of a heat resistance and the like is frequently used in the fields of electric and electronic parts. Recently, polyamide resins are developed as an additive or a curing agent for improving characteristics of a usual epoxy resin or the like, and also an epoxy resin composition containing the same as a component typically forms a cured product having excellent heat resistance, mechanical properties, chemical resistance and the like and is widely utilized in fields for adhesives, paints, laminates, shaping materials, casting materials and so on. For example, WO 2004/048436 and JP-A-2000-313787 disclose an epoxy resin composition containing an epoxy resin and a phenolic hydroxyl group-containing polyamide resin as an epoxy resin composition, which is excellent in the heat resistance and the flame retardance and useful as a material for a flexible printed wiring board.

However, the epoxy resin composition disclosed in WO 2004/048436 and JP-A-2000-313787 is insufficient in the flexibility, and has a residual phosphoric ion because the phenolic hydroxyl group-containing polyamide resin used in this epoxy resin composition is obtained by condensation between a diamine component and a dicarboxylic acid component in the presence of a phosphorous acid compound. Although the residual phosphoric ion can be removed by washing the phenolic hydroxyl group-containing polyamide resin with water, as the molecular weight of the polyamide resin becomes higher, the viscosity increases and the sufficient washing with water becomes difficult, and hence the polyamide resin may cause insulation failure when being used as a material for electric and electronic parts.

On the other hand, as a material improving the solvent resistance and adhesion properties without damaging the heat resistance and flexibility is known the use of a rubber-modified polyamide resin (JP-A-H10-287806). However, the resin and the resin composition disclosed in JP-A-H10-287806 are insufficient in the flame retardance and electrical properties though the flexibility is excellent, and particularly the rubber moiety may be embrittled to lower the film characteristics.

### DISCLOSURE OF THE INVENTION

It is, therefore, an object of the invention to provide a phenolic hydroxyl group-containing rubber-modified polyamide resin capable of providing a cured product with excellent heat resistance, adhesion properties, electrically insulating property and flame retardance and having a sufficient flexibility when being shaped into a film. It is another object of the invention to provide an epoxy resin composition containing such a phenolic hydroxyl group-containing rubber-modified polyamide resin and an epoxy resin.

The inventors have made various studies in order to solve the above subject-matter, and as a result, the invention has been accomplished.

That is, the summary and construction of the invention are as follows.

1. A phenolic hydroxyl group-containing rubber-modified polyamide resin characterized by having in its molecule (a) a phenolic hydroxyl group-containing aromatic polyamide segment represented by the following formula (1):

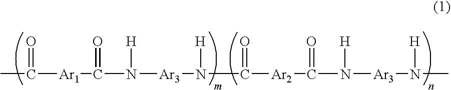

(in the formula (1), m and n are average values and satisfy a relationship of 0.005≦n/(m+n)≦1.00 and m+n is an integer of 2-200, and Ar₁ is a bivalent aromatic group, Ar₂ is a bivalent aromatic group having a phenolic hydroxyl group and Ar₃ is a bivalent aromatic group) and (b) a hydrogenated butadiene polymer segment.

2. The phenolic hydroxyl group-containing rubber-modified polyamide resin according to the item 1, wherein the hydrogenated butadiene polymer segment (b) is represented by the following formula (2):

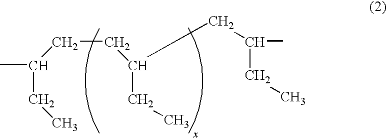

(in the formula (2), x is an average value and is an integer of 3-200).

3. The phenolic hydroxyl group-containing rubber-modified polyamide resin according to the item 1 or 2, wherein the phenolic hydroxyl group-containing aromatic polyamide segment (a) is represented by the following formula (3):

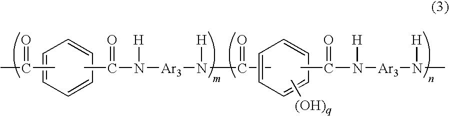

(in the formula (3), m and n are average values and satisfy a relationship of 0.005≦n/(m+n)≦1.00 and m+n is an integer of 2-200, and Ar₃ is a bivalent aromatic group and q is an average substituent number and is an integer of 1-4).

4. An epoxy resin composition comprising (A) a phenolic hydroxyl group-containing rubber-modified polyamide resin according to any one of the items 1-3 and (B) an epoxy resin.

5. The epoxy resin composition according to the item 4, which further contains (C) a phenolic hydroxyl group-containing polyamide resin having the phenolic hydroxyl group-containing aromatic polyamide segment (a).

6. The epoxy resin composition according to the item 4 or 5, which is shaped into a film.

7. An adhesion sheet for a flexible printed wiring board characterized by using an epoxy resin composition according to the item 6.

8. A cured product of an epoxy resin composition formed by heat-curing an epoxy resin composition according to any one of the items 4-6.

9. A cured product of an adhesion sheet for a flexible printed wiring board formed by heat-curing an adhesion sheet for a flexible printed wiring board according to the item 7.

10. A reinforcing plate for a flexible printed wiring board characterized by using a cured layer of an epoxy resin composition according to the item 6.

11. A cover lay for a flexible printed wiring board characterized by using a cured layer of an epoxy resin composition according to the item 6.

12. A metal-clad resin laminate characterized by contacting a one-side face or both faces of a cured layer of an epoxy resin composition according to the item 6 with a one-side face of a metal foil layer or a resin face of a one-side metal-clad resin laminate.

13. A flexible printed wiring board characterized by using at least one selected from the group consisting of an epoxy resin composition according to the item 6, an adhesion sheet for a flexible printed wiring board according to the item 7, a reinforcing plate for a flexible printed wiring board according to the item 10, a cover lay for a flexible printed wiring board according to the item 11 and a metal-clad resin laminate according to the item 12.

14. An interlaminar insulating film characterized by using an epoxy resin composition according to any one of the items 4-6 or a cured product of an epoxy resin composition according to the item 8.

The phenolic hydroxyl group-containing rubber-modified polyamide resin according to the invention can provide a cured product having excellent heat resistance, adhesion properties, electrically insulating property and flame retardance, and is excellent in the flexibility and electric reliability when being shaped into a film. Also, the epoxy resin composition according to the invention has a sufficient flexibility and is excellent in the electric reliability when being shaped into a thin film. Furthermore, the film-shaped epoxy resin composition according to the invention and the cured product thereof are excellent in the heat resistance, adhesion properties and flame retardance while maintaining the sufficient flexibility and the electric reliability, so that they may be widely used in a flexible printed (print) wiring board, a semiconductor insulating material and the like or is very useful in the field of electric materials such as electric substrate, insulating film and so on.

### BEST MODE FOR CARRYING OUT THE INVENTION

The invention will be described in detail below. The phenolic hydroxyl group-containing rubber-modified polyamide resin according to the invention is characterized by having in its molecule (a) a phenolic hydroxyl group-containing aromatic polyamide segment represented by the formula (1) and (b) a hydrogenated butadiene polymer segment. At this moment, the phenolic hydroxyl group-containing rubber-modified polyamide resin according to the invention has the segment (a) being excellent in the heat resistance and flame retardance and the segment (b) being excellent in the flexibility, solvent resistance and adhesion properties in its molecule, so that it can develop characteristics of both the segments and is suitable as an additive for an epoxy resin composition.

The segment (a) in the phenolic hydroxyl group-containing rubber-modified polyamide resin according to the invention is required to be represented by the formula (1) and is preferable to be represented by the formula (3).

In the formulae (1) and (3), Ar₃ is required to be a bivalent aromatic group. For example, there is preferably mentioned an aromatic residue group represented by the following formula (4):

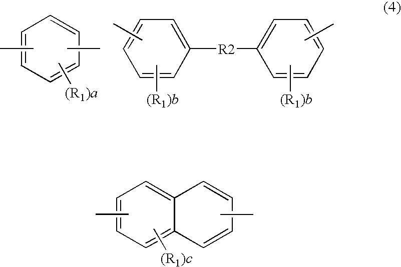

(in the formula (4), R₁ is hydrogen atom or a substituent having a carbon number of 1-6 and optionally containing O, S, P, F or Si, and R2 is a direct bond (single bond) or an oxygen atom (—O—), a sulfur atom (—S—), —SO₂—, —N═N— or a bond having a carbon number of 1-6 and optionally containing O, N, S, P, F or Si, and a, b, and c are average substituent number provided that each of a and b is an integer of 0-4 and c is an integer of 0-6). It may have two or more of such bivalent aromatic groups. Among them, it is further preferable to be an aromatic residue group represented by the following formula (4′):

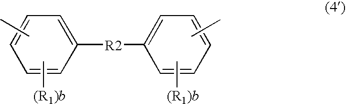

(wherein R₁, R2 and b in the formula (4′) are the same as R₁, R2 and b in the formula (4)).

In the formulae (4) and (4′), as a preferable R₁ are mentioned hydrogen atom, hydroxyl group, a chain alkyl group such as methyl group, ethyl group, propyl group, butyl group, pentyl group, hexyl group or the like, and a cyclic alkyl group such as cyclobutyl group, cyclopentyl group, cyclohexyl group or the like. R₁s may be same or different, and further it is preferable that all of them are the same. As a preferable R2 are mentioned a direct bond, —O—, —SO₂—, —CO—, —(CH₂)₁₋₆—, —C(CH₃)₂—, —C(CF₃)₂— and the like. Moreover, it is preferable that two —NH— groups as the aromatic residue group in the formula (4′) are bonded to carbon atoms at position numbers of 3 and 4′ or position numbers of 4 and 4′.

In the formula (1), Ar₁ is a bivalent aromatic group, i.e. a bivalent group of an aromatic hydrocarbon or a substituted aromatic hydrocarbon. As the aromatic hydrocarbon are mentioned, for example, benzene, biphenyl, naphthalene and the like, and among them, benzene is preferable. As the substituent are mentioned substituents having a carbon number of 1-6 and optionally containing O, S, P, F or Si. Moreover, Ar₁s may be same or different.

In the formula (1), Ar₂ is a bivalent aromatic group having a phenolic hydroxyl group, i.e. a bivalent group of an aromatic hydrocarbon having a phenolic hydroxyl group or an aromatic hydrocarbon having a phenolic hydroxyl group and another substituent. As the aromatic hydrocarbon having the phenolic hydroxyl group are mentioned phenol, biphenol, naphthol and the like, and among them, phenol is preferable. As another substituent are mentioned substituents having a carbon number of 1-6 and optionally containing O, S, P, F or Si, and so on. Moreover, Ar₂s may be same or different.

In the formulae (1) and (3), m and n are shown by an average value and is required to satisfy a relationship of 0.005≦n/(m+n)≦1.00 (wherein m+n is an integer of 2-200). In the formula (3), q is an average functional number of the phenolic hydroxyl group and is an integer of 1-4.

On the other hand, the segment (b) in the phenolic hydroxyl group-containing rubber-modified polyamide resin according to the invention is required to be a hydrogenated butadiene polymer segment, wherein the hydrogenated butadiene polymer segment (b) is a segment having butadiene as a repetitive unit and hydrogenated at an unsaturated bond of butadiene portion. As butadiene forming the hydrogenated butadiene polymer segment are mentioned 1,2-butadiene, 1,3-butadiene and the like. When 1,3-butadiene is used as butadiene forming the hydrogenated butadiene polymer segment (b), it is preferable to insert 1,3-butadiene into the segment in form of vinyl bond (1,2-bond), but may include a case of inserting into the segment in form of 1,4-bond. Furthermore, in the hydrogenated butadiene polymer segment (b), not less than 80% of unsaturated bond in butadiene portion is preferably hydrogenated, and it is particularly preferable that the unsaturated bond is hydrogenated completely. Moreover, the hydrogenated butadiene polymer segment (b) is preferable to have an average repetitive unit number of 3-200. Considering the above, the hydrogenated butadiene polymer segment (b) is particularly preferable to be a segment represented by the formula (2).

The phenolic hydroxyl group-containing rubber-modified polyamide resin according to the invention is obtained by reacting (C) a phenolic hydroxyl group-containing polyamide resin having the segment (a) represented by the formula (1) (which may be called as polyamide resin (C) hereinafter) with a hydrogenated polybutadiene having carboxyl groups or amino groups at its both terminals. The polyamide resin (C) may be produced by applying a method described in, for example, Japanese Patent No. 2969585. That is, an aromatic diamine material is condensed with a phenolic hydroxyl group-containing aromatic dicarboxylic acid material (which may be used together with an aromatic dicarboxylic acid material containing no phenolic hydroxyl group, and a combination of both cases may be simply called as an aromatic dicarboxylic acid material hereinafter). In the condensation, when the aromatic diamine material is used excessively as compared with the aromatic dicarboxylic acid material, a polyamide resin (C) having an amino group at its terminal is obtained, while when the aromatic dicarboxylic acid material is used excessively as compared with the aromatic diamine material, a polyamide resin (C) having a carboxyl group at its terminal is obtained. The excessive amount is usually not less than 1% as a molar ratio, and the upper limit thereof is not more than 100%, preferably not more than 10%. The reaction of the polyamide resin (C) with the hydrogenated polybutadiene having carboxyl groups or amino groups at its both terminals can be conducted according to the above method of producing the polyamide resin (C). That is, a polyamide resin (C) obtained from the excessive amount of the aromatic diamine material and having amino groups at its both terminals is condensed with a hydrogenated polybutadiene having carboxyl groups at its both terminals, or a polyamide resin (C) obtained from the excessive amount of the aromatic dicarboxylic acid material and having carboxyl groups at its both terminals is condensed with a hydrogenated polybutadiene having amino groups at its both terminals. Among them, the former case is preferable.

In the production of the polyamide resin (C), the condensation reaction of the aromatic diamine material and the aromatic dicarboxylic acid material may be conducted with a phosphorus-based condensing agent or with an organic solvent in the presence of a pyridine derivative. In this case, the molecular weight of the resulting polyamide resin (C) can be increased by adding an inorganic salt such as lithium chloride, calcium chloride or the like. As the phosphorus-based condensing agent is preferable a phosphite. According to this production method, a phenolic hydroxyl group-containing polyamide resin (C) can be easily produced without protecting a phenolic hydroxyl group as a functional group and further without causing a reaction between the phenolic hydroxyl group and another reaction group such as carboxyl group or amino group. Moreover, a higher temperature is not required in the polycondensation, so that there is a merit that the polycondensation may be conducted at a temperature of not higher than about 150° C.

The synthesis method of the polyamide resin (C) providing the phenolic hydroxyl group-containing aromatic polyamide segment (a) will be described in more detail below. As the aromatic diamine material are mentioned a phenylenediamine derivative such as m-phenylenediamine, p-phenylenediamine, m-tolylenediamine or the like; a diaminodiphenyl ether derivative such as 4,4′-diaminodiphenyl ether, 3,3′-dimethyl-4,4′-diaminodiphenyl ether, 3,4′-diaminodiphenyl ether or the like; a diaminodiphenyl thioether derivative such as 4,4′-diaminodiphenyl thioether, 3,3′-dimethyl-4,4′-diaminodiphenyl thioether, 3,3′-diethoxy-4,4′-diaminodiphenyl thioether, 3,3′-diaminodiphenyl thioether, 3,3′-dimethoxy-4,4′-diaminodiphenyl thioether or the like; a diaminobenzophenone derivative such as 4,4′-diaminobenzophenone, 3,3′-dimethyl-4,4′-diaminobenzophenone or the like; a diaminodiphenyl sulfon derivative such as 4,4′-diaminodiphenyl sulfoxide, 4,4′-diaminodiphenyl sulfon or the like; a benzidine derivative such as benzidine, 3,3′-dimethylbenzidine, 3,3′-dimethoxybenzidine, 3,3′-diaminobiphenyl or the like; a xylylenediamine derivative such as p-xylylenediamine, m-xylylenediamine, o-xylylenediamine or the like; a diaminodiphenyl methane derivative such as 4,4′-diaminodiphenyl methane, 3,3′-diaminodiphenyl methane, 4,4′-diamino-3,3′-dimethyldiphenyl methane, 4,4′-diamino-3,3′-diethyldiphenyl methane, 4,4′-diamino-3,3′,5,5′-tetramethyldiphenyl methane, 4,4′-diamino-3,3′,5,5′-tetraethyldiphenyl methane or the like; and so on. Among them, the phenylenediamine derivative, diaminodiphenyl methane derivative or the diaminodiphenyl ether derivative is preferable, and the diaminodiphenyl ether derivative is further preferable, and 3,4′-diaminodiphenyl ether or 4,4′-diaminodiphenyl ether is particularly preferable from a viewpoint of solvent solubility and flame retardance of the resulting polymer.

Among the aromatic dicarboxylic acid materials, a phenolic hydroxyl group-containing aromatic dicarboxylic acid material is not particularly limited as long as the aromatic ring has a structure having two carboxyl groups and one or more hydroxyl groups, and may include a dicarboxylic acid having one hydroxyl group and two carboxyl group on a benzene ring such as 5-hydroxyisophthalic acid, 4-hydroxyis ophthalic acid, 2-hydroxyisophthalic acid, 3-hydroxyisophthalic acid, 2-hydroxyterephthalic acid or the like. From viewpoints of solvent solubility and purity of the resulting polymer as well as electric properties when being used in an epoxy resin composition and an adhesion properties to a metal foil and a polyimide, 5-hydroxyisophthalic acid is preferable. As the aromatic dicarboxylic acid material other than the phenolic hydroxyl group-containing aromatic dicarboxylic acid material are mentioned, for example, phtalic acid, isophthalic acid, terephthalic acid and the like, and isophthalic acid is preferable. The content of the phenolic hydroxyl group-containing aromatic dicarboxylic acid material is preferable to be not less than 0.5 mol % but not more than 100 mol % in the aromatic dicarboxylic acid material. This feed ratio determines n/(m+n) in the formulae (1) and (3).

As the phosphite usable in the synthesis of the polyamide resin (C) are mentioned, but are not limited to, triphenyl phosphite, diphenyl phosphite, tri-o-tolyl phosphite, di-o-tolyl phosphite, tri-m-tolyl phosphite, tri-p-tolyl phosphite, di-p-tolyl phosphite, di-p-chlorophenyl phosphite, tri-p-chlorophenyl phosphite, di-p-chlorophenyl phosphite and so on.

As the pyridine derivative used together with the phosphite may be mentioned pyridine, 2-picoline, 3-picoline, 4-picoline, 2,4-lutidine and so on.

The condensing agent used in the synthesis of the polyamide resin (C) consists of, for example, the phosphite and the pyridine derivative, wherein the pyridine derivative is usually added to an organic solvent in use. The organic solvent does not substantially react with the phosphite and has a property of well dissolving the aromatic diamine material and the aromatic dicarboxylic acid material but also is desirable to be a good solvent to the polyamide resin (C) as a reaction product. As the organic solvent are mentioned an amide-based solvent such as N-methylpyrrolidone, dimethyl acetoamide or the like; toluene, methylethylketone (MEK), and a mixed solvent thereof with the amide-based solvent. Among them, N-methyl-2-pyrrolidone is preferable. The content of the pyridine derivative in the mixture of the pyridine derivative and the organic solvent is preferable to be commonly 5-30 mass %.

In order to increase the polymerization degree of the polyamide resin (C), it is preferable to add an inorganic salt such as lithium chloride, calcium chloride or the like in addition to the above phosphite and pyridine derivative.

Next, the most preferable production method of the polyamide resin (C) will be described concretely. At first, a phosphite and an inorganic salt are added to a mixed solvent of organic solvent containing a pyridine derivative, and then 5-hydroxyisophthalic acid (including isophthalic acid in some cases) is added thereto, and further 3,4′-diaminodiphenyl ether or 4,4′-diaminodiphenyl ether is added in an amount of 101-200 mol per 100 mol of dicarboxylic acid, and thereafter the resulting mixture is heated in an inert atmosphere of nitrogen or the like with stirring to obtain a polyamide resin (C) having amino groups at its both terminals. Subsequently, in order to produce the phenolic hydroxyl group-containing rubber-modified polyamide resin according to the invention, 1-100 mol of a hydrogenated butadiene polymer having carboxyl groups at its both terminals and diluted with an organic solvent is added to 100 mol of the resulting polyamide resin (C) and heated in an inert atmosphere of nitrogen or the like with stirring to conduct reaction. After the completion of the reaction, the reaction mixture is added with a poor solvent such as water, methanol, hexane or the like, or the reaction mixture is charged into such a poor solvent to isolate a purified polymer, and then the purification is carried out by reprecipitation process to remove a by-product, inorganic salt and the like, whereby there can be obtained a phenolic hydroxyl group-containing rubber-modified polyamide resin having in its molecule (a) a phenolic hydroxyl group-containing aromatic polyamide segment represented by the formula (1) and (b) a hydrogenated butadiene polymer segment.

The hydrogenated butadiene polymer is a hydrogenated product of a butadiene polymer, and is not particularly limited as long as it is a compound having carboxyl groups or amino groups at its both terminals, and is introduced into the phenolic hydroxyl group-containing rubber-modified polyamide resin according to the invention as an elastomer segment. For instance, as mentioned above, if both terminals of the polyamide resin (C) are amino groups, a hydrogenated butadiene polymer having carboxyl groups at its both terminals is selected, while if both terminals of the polyamide resin (C) are carboxyl groups, a hydrogenated butadiene polymer having amino groups at its both terminals is selected. As the butadiene polymer are mentioned a polymer of 1,2-butadiene, and a polymer of 1,3-butadiene. As a hydrogenated product of 1,2-butadiene polymer having carboxyl groups at its both terminals is preferably mentioned CI-1000 made by Nippon Soda Co., Ltd. The amount of the hydrogenated butadiene polymer used is usually 20-200 parts by mass per 100 parts by mass of the polyamide resin (C), and is preferable to be equal thereto. Also, a molar ratio (X/Y) of carboxyl group or amino group (X) at both terminals of the hydrogenated butadiene polymer to carboxyl group or amino group (Y) at both terminals of the polyamide resin (C) is preferable to be a range of 0.05-2.0.

In the synthesis of the polyamide resin (C), the amount of the phosphite added as a phosphorus-based condensing agent is not particularly limited as long as it is commonly equal to or more than a mole of amino group in the aromatic diamine material, but more than 30 times as a mole ratio is not efficient. In case of using a triphosphite, since a by-produced diphosphite is also a condensing agent, the addition amount may be usually about 80 mol %. On the other hand, the amount of the pyridine derivative added is required to be equal to or more than a mole of amino group in the aromatic diamine material, but is frequently a considerably excessive amount because it actually serves as a reaction solvent. The amount of the mixture of the pyridine derivative and the organic solvent used is preferable to be such an amount that a concentration in the reaction mixture of a theoretically obtained phenolic hydroxyl group-containing polyamide resin (C) or subsequently producible phenolic hydroxyl group-containing rubber-modified polyamide resin according to the invention is 5-30 mass %. In the synthesis of the polyamide resin (C), the reaction temperature is preferable to be 60-180° C., while the reaction time is largely affected by the reaction temperature but is usually several minutes to 20 hours. In any cases, it is preferable to agitate the reaction system till the maximum viscosity indicating the highest polymerization degree is obtained.

Furthermore, when 5-hydroxyisophthalic acid (including isophthalic acid in some cases) and 3,4′-diaminodiphenyl ether or 4,4′-diaminodiphenyl ether are used in equimolar amounts in the most preferable production method of the polyamide resin (C), there can be obtained a polyamide resin (C) having a most preferable average polymerization degree that an average repetitive unit number (m+n) is about 2-100. In the subsequent production of the phenolic hydroxyl group-containing rubber-modified polyamide resin according to the invention, a most preferable average polymerization degree can be obtained when total carboxyl groups and total amino groups in 5-hydroxyisophthalic acid (including isophthalic acid in some cases), 3,4′-diaminodiphenyl ether or 4,4′-diaminodiphenyl ether and the hydrogenated butadiene polymer are used in equimolar amounts.

Moreover, when the phenolic hydroxyl group-containing rubber-modified polyamide resin according to the invention has a preferable polymerization degree, the molecular weight as converted to polystyrene through GPC (gel permeation chromatography) is a range of 3000-60000 as a number average molecular weight and a range of 10000-250000 as a weight average molecular weight. In general, the preferable average polymerization degree is judged by referring the molecular weight. When the weight average molecular weight is less than 10000, the film forming property and the development of properties as an aromatic polyamide resin are insufficient. While, when the weight average molecular weight exceeds 250000, the polymerization degree is too high and there is a fear of deteriorating the solvent solubility but also the fabricating property.

As a simple method of adjusting the polymerization degree of the phenolic hydroxyl group-containing rubber-modified polyamide resin according to the invention may be mentioned, for example, a method of excessively using either the aromatic diamine material or the aromatic dicarboxylic acid material in the synthesis of the polyamide resin (C).

The epoxy resin composition according to the invention is characterized by containing the above phenolic hydroxyl group-containing rubber-modified polyamide resin (A component in the epoxy resin composition hereinafter) and an epoxy resin (B), and is preferable to further contain the phenolic hydroxyl group-containing polyamide resin (C). When a mixture of the phenolic hydroxyl group-containing rubber-modified polyamide resin (A) and the polyamide resin (C) is used as a curing agent for the epoxy resin (B), the flame retardance and heat resistance of a cured product of the epoxy resin composition according to the invention can be improved. The epoxy resin (B) is not particularly limited as long as it is a resin having an aromatic ring such as benzene ring, biphenyl ring or naphthalene ring and two or more epoxy groups in one molecule. Concretely, the epoxy resin (B) includes, but is not limited to, a novolac type epoxy resin, a xylylene skeleton-containing phenol novolac type epoxy resin, a biphenyl skeleton-containing novolac type epoxy resin, a bisphenol A-type epoxy resin, a bisphenol F-type epoxy resin, tetramethyl biphenol type epoxy resin and the like.

In the epoxy resin composition according to the invention, the other curing agent may be compounded in addition to the phenolic hydroxyl group-containing rubber-modified polyamide resin (A) (including the polyamide resin (C), if necessary) and the epoxy resin (B). As a concrete example of the other curing agent compounded are mentioned, but are not limited to, diaminodiphenyl methane, diethylenetriamine, triethylenetetramine, diaminodiphneyl sulfon, isophorone diamine, dicyandiamide, a polyamide resin synthesized from a dimer of linolenic acid and ethylenediamine, phthalic anhydride, trimellitic anhydride, pyromellitic anhydride, maleic anhydride, tetrahydrophthalic anhydride, methyltetrahydrophthalic anhydride, methylnadic anhydride, hexahydrophthalic anhydride, methylhexahydrophthalic anhydride, another phenolic hydroxyl group-containing resin, triphenylmethane and a modified product thereof, imidazole, BF₃-amine complex, guanidine derivatives and so on. When the epoxy resin composition according to the invention contains the other curing agent, a ratio of the polyamide resin (A) occupied in the total of the phenolic hydroxyl group-containing rubber-modified polyamide resin (A) (including the polyamide resin (C), if necessary) and the other curing agent is usually not less than 20 mass %, preferably not less than 30 mass %.

As the curing agent used in the epoxy resin composition according to the invention, the total active hydrogen equivalent of the phenolic hydroxyl group-containing rubber-modified polyamide resin (A) and the polyamide resin (C) used if necessary and the other curing agent is preferable to be 0.7-1.2 per 1 equivalent of eposy group in the epoxy resin (B). When the total active hydrogen equivalent is less than 0.7 or exceeds 1.2 per 1 equivalent of epoxy group in the epoxy resin (B), there is a fear that the curing of the epoxy resin composition according to the invention becomes incomplete and good curing properties are not obtained. The active hydrogen equivalent of the phenolic hydroxyl group-containing rubber-modified polyamide resin (A) and the polyamide resin (C) can be calculated from the amounts of the aromatic dicarboxylic acid material and the aromatic diamine material used and charged in the reaction.

In the epoxy resin composition according to the invention may be used a curing promoter. As a concrete example of the curing promoter are mentioned, for example, imidazoles such as 2-methylimidazole, 2-ethylimidazole, 2-ethy1-4-methylimidazole, 2-phenyl-4,5-dihydroxymethylimidazole, 2-phneyl-4-methyl-hydroxymethylimidazole and the like; tertiary amines such as 2-(dimethylaminomethyl)phenol, 1,8-diaza-bicyclo(5,4,0)undecene-7 and the like; phosphines such as triphenylphosphine and the like; metallic compounds such as tin octylate and the like. The content of the curing promoter is preferable to be 0.1-5.0 parts by mass based on 100 parts by mass of the epoxy resin (B).

The epoxy resin composition according to the invention may contain an inorganic filler, if necessary. As a concrete example of the inorganic filler are mentioned, for example, silica, aluminum hydroxide, magnesium hydroxide, calcium carbonate, calcium phosphate, alumina, talc, glass short fibers and the like. In the epoxy resin composition according to the invention, the content of the inorganic filler is preferably 0-90 mass %. Moreover, various additives such as a silane coupling agent, releasing agents such as stearic acid, palmitic acid, zinc stearate, calcium stearate and the like, pigment and so on may be added to the epoxy resin composition according to the invention.

The epoxy resin composition according to the invention is obtained by uniformly mixing the above components. Also, a cured product of the epoxy resin composition according to the invention can be easily obtained by curing the above epoxy resin composition through a method similar to the conventionally known method. Concretely, the cured product of the epoxy resin composition according to the invention can be obtained by sufficiently uniformly mixing an epoxy resin (B), a polyamide resin (A), and, if necessary, a polyamide resin (C), another curing agent, a curing promoter, an inorganic filler and another additives through an extruder, a kneader, rolls or the like to obtain an epoxy resin composition, shaping the epoxy resin composition through a method such as a melt casting method, a transfer molding method, an injection molding method, a compression molding method or the like, and further heating at 80-200° C. for 2-10 hours.

Also, a film shaped from the epoxy resin composition according to the invention and a cured product thereof are obtained from a varnish of the epoxy resin composition according to the invention in a solvent. As the solvent used in the varnish are mentioned γ-butyrolactones, an amide-based solvent such as N-methylpyrrolidone (NMP), N,N-dimethylformamide (DMF), N,N-dimethylacetoamide, N,N-dimethylimidazolidinone or the like; sulfon such as tetramethylene sulfon or the like; an ether-based solvent such as diethylene glycol dimethyl ether, diethylene glycol diethyl ether, propylene glycol, propylene glycol monomethyl ether, propylene glycol monomethyl ether monoacetate, propylene glycol monobutyl ether or the like; a ketone-based solvent such as methyl ethyl ketone, methyl isobutyl ketone, cyclopentanone, cyclohexanone or the like; and an aromatic solvent such as toluene, xylene or the like. The solvent can be used so that a solid concentration in the varnish (concentration of components other than the solvent) is usually 20-80 mass %, preferably 30-70 mass %. Moreover, the cured product of the film shaped from the epoxy resin composition according to the invention can be used a cured layer of the epoxy resin composition according to the invention.

Further, the film shaped from the epoxy resin composition according to the invention is obtained by applying the varnish onto, for example, a flat support through various well-known application methods such as a gravure coating method, a screen printing method, a metal masking method, a spin coating method and the like and then drying it. At this moment, the thickness of the film after the drying is preferable to be, for example, 5-500 μm. Also, the application method is properly selected in accordance with kind, form and size of a substrate, and a thickness of a coating film. As the substrate are mentioned a film made from polyamide, polyimide, polyamideimide, polyarylate, polyethylene terephthalate, polybutylene terephthalate, polyether ether ketone, polyether imide, polyether ketone, polyketone, polyethylene, polypropylene and a copolymer thereof or the like, and a metal foil such as copper foil or the like. Among them, the polyimide or the metal foil is preferable. The cured product can be obtained by further heating the film. The film of the epoxy resin composition according to the invention (including a cured layer of the epoxy resin composition according to the invention) is preferably applied to an adhesion sheet for a flexible printed wiring board, a reinforcing plate for a flexible printed wiring board, a cover lay for a flexible printed wiring board or a one-side or both sides metal-clad resin laminate (hereinafter they are called as a material for flexible printed wiring board together). The epoxy resin composition according to the invention acts as an adhesive or a resin layer in the material for flexible printed wiring board. In these applications, the aforementioned flat support is preferable to act as a releasing film. Moreover, the metal-clad resin laminate is characterized by contacting one-side face or both faces of the cured layer of the epoxy resin composition according to the invention with one-side face of the metal foil layer or a resin face of the one-side face metal-clad resin laminate. Also, the flexible printed wiring board according to the invention is characterized by using at least one of the aforementioned materials for flexible printed wiring board. Furthermore, the epoxy resin composition according to the invention and the cured product thereof are excellent in the adhesion properties and electric characteristics, so that they may be used as a thermosetting interlaminar insulating film in a substrate for semiconductor such as a build-up substrate or the like.

Also, the cured product of the epoxy resin composition according to the invention can be obtained by impregnating the varnish into a substrate such as glass fibers, carbon fibers, polyester fibers, aramid fibers, xyron fibers, alumina fibers, paper or the like and heat-drying to obtain a prepreg, and then thermally press-molding it. In this case, the amount of the solvent used is usually 10-70 mass %, preferably 15-70 mass % in the mixture of the epoxy resin composition according to the invention and the solvent.

### Examples

The invention will be concretely described with reference to examples and comparative example, but is not limited thereto. Also, the active hydrogen equivalent is a theoretical value calculated by the following method.

(1) Active Hydrogen Equivalent

It is calculated by subtracting a water quantity dehydrated by polymerization from total weight of materials constituting the phenolic hydroxyl group-containing rubber-modified polyamide resin and dividing the obtained weight by mol number of phenolic hydroxyl group+terminal functional group.

### Synthesis Example 1 of Phenolic Hydroxyl Group-Containing Polyamide Resin

A flask provided with a thermometer, a cooling pipe and a stirrer is purged with nitrogen gas and added with 1.8 g (0.010 mol) of 5-hydroxyisophthalic acid, 81.3 g (0.490 mol) of isophthalic acid, 102 g (0.509 mol) of 3,4′-diaminodiphenyl ether, 3.4 g of lithium chloride, 344 g of N-methyl-2-pyrrolidone and 115.7 g of pyridine, which are dissolved with stirring and then added with 251 g (0.809 mol) of triphenylphosphite and reacted at 90° C. for 8 hours to obtain a reaction liquid of a phenolic hydroxyl group-containing polyamide resin (C-1) having a segment represented by the following formula (5) (in the formula (5), n/(m+n) is 0.020 (charging molar ratio)) and amino groups at its both terminals:

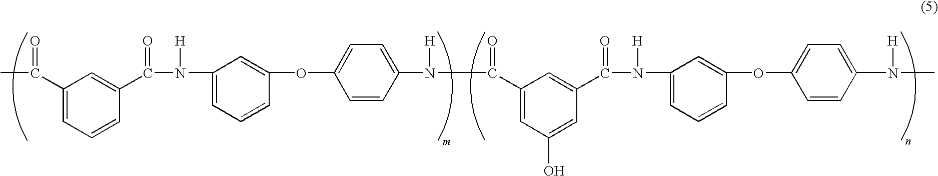

The reaction liquid is cooled to room temperature and charged into 500 g of methanol, and the precipitated resin is filtered off and further washed with 500 g of methanol and then purified by refluxing with methanol. Next, the purified product is cooled to room temperature and filtered, and then the filtrate is dried to obtain a resin (C-1) in powder form. The thus obtained resin (C-1) is 160 g, which is a yield of 96%. Moreover, the molecular weight of the resin (C-1) is 24000 as a number average molecular weight converted to polystyrene and 100000 as a weight average molecular weight converted to polystyrene. Further, the active hydrogen equivalent capable of reacting with epoxy group in the resin (C-1) is 6000 g/eq. as a calculated value (hydroxyl equivalent is 16700 g/eq.).

### Example 1

A flask provided with a thermometer, a cooling pipe and a stirrer is purged with nitrogen gas and added with 1.165 g (0.006 mol) of 5-hydroxyisophthalic acid, 7.223 g (0.043 mol) of isophthalic acid, 11.297 g (0.056 mol) of 3,4′-diaminodiphenyl ether, 0.955 g of lithium chloride, 89.710 g of N-methyl-2-pyrrolidone and 35.678 g of pyridine, which are dissolved with stirring and added with 28.330 g of triphenylphosphite and reacted at 90° C. for 5 hours to obtain a polyamide resin having amino groups at its both terminals (equivalent of amino group: 1280 g/eq). To the polyamide resin is added a solution of 12.820 g (0.006 mol) of a hydrogenated butadiene polymer having carboxyl groups at its both terminals (CI-1000, made by Nippon Soda Co., Ltd. average molecular weight: 2142) in 6.410 g of toluene and 6.410 g of N-methyl-2-pyrrolidone, which are further reacted for 3 hours to obtain a reaction liquid of a phenolic hydroxyl group-containing rubber-modified polyamide resin (A-1) comprised of a segment represented by the following formula (6):

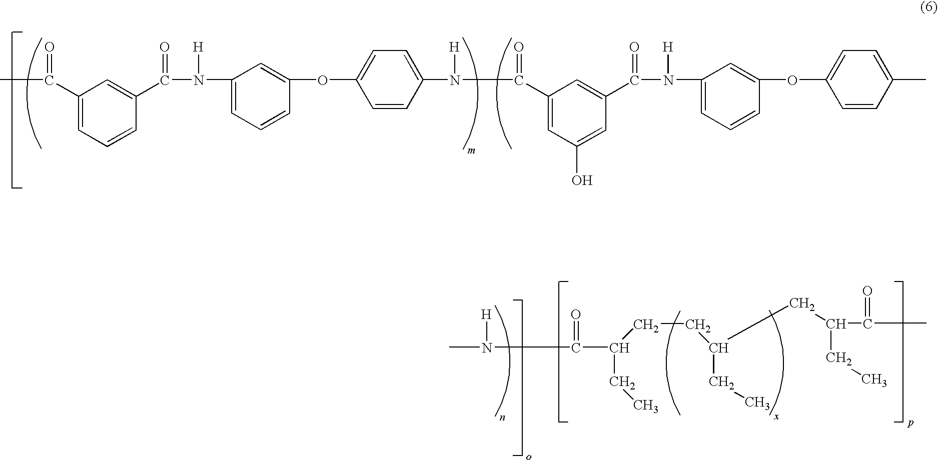

(in the formula (6), n/(m+n)=0.128 (charging molar ratio), and x=36 and p/o=0.65 (mass ratio)) wherein (a) a phenolic hydroxyl group-containing aromatic polyamide segment and (b) a hydrogenated butadiene polymer segment form a block copolymer. The reaction liquid is cooled to room temperature and added dropwise with 60 g of methanol and 130 g of water, and the resulting precipitated resin is filtered off and purified by refluxing with water and refluxing with methanol. Then, it is cooled to room temperature and filtered and then the filtrate is dried to obtain a resin (A-1) in form of powder. The thus obtained resin (A-1) is 29 g, which is a yield of 95.1%. Moreover, the molecular weight of the resin (A-1) is 21600 as a number average molecular weight converted to polystyrene and 91100 as a weight average molecular weight converted to polystyrene. In addition, the active hydrogen equivalent capable of reacting with epoxy group in the resin (A-1) is 4056 g/eq. as a calculated value (hydroxyl equivalent is 4765 g/eq.).

### Examples 2 and 3

A varnish of an epoxy resin composition according to the invention in a solvent is obtained by using the phenolic hydroxyl group-containing polyamide resin (C-1) obtained in Synthesis Example 1 and the phenolic hydroxyl group-containing rubber-modified polyamide resin (A-1) obtained in Example 1 and mixing them according to a compounding recipe (part by mass) shown in Table 1.

TABLE 1

| | Example 2 | Example 3 |
|---|---|---|
| A-1 | 44.54 | 28.37 |
| C-1 | | 18.80 |
| NC-3000 (*1) | 4.45 | 2.84 |
| GPH-65 (*2) | 1.01 | |
| 2PHZ (*3) | 0.22 | 0.14 |
| NMP | 200.0 | 200.0 |

(*1) made by Nippon Kayaku Co., Ltd. biphenyl-skeleton epoxy resin, epoxy equivalent: 280 g/eq.
(*2) made by Nippon Kayaku Co., Ltd. biphenyl-skeleton phenolic hydroxyl group-containing resin, active hydrogen equivalent: 205 g/eq.
(*3) made by Shikoku Kasei Co., Ltd. 2-phenyl-4,5-dihydroxymethylimidazole

### Examples 4 and 5

A film-shaped epoxy resin composition according to the invention (hereinafter referred to as a film) (Examples 4-5) is obtained by applying the varnish obtained in Examples 2-3 onto a PET (polyethylene terephthalate) film so as to render a thickness after drying into 10 μm, drying at 140° C. for 3 minutes and then removing the PET film.

### Examples 6 and 7

A commercially available polyimide copper-clad laminate Yupicell D (trade name) (made by Ube Industries, Ltd.) is used to form comb-type electrodes defined in IPC-SM-840 (conductor/line=100 μm/100 μm), which is used as a circuit for evaluation. The film prepared in Examples 4-5 is attached to the comb-type electrodes and pressed under heating at 170° C. and 5 MPa for 60 minutes to form a test sample for electric reliability. Pressure cooker bias test (PCBT) is carried out by applying a direct current voltage of 50 V between the electrodes under environments of 121° C. and 100% RH for 500 hours as an upper limit with an ion migration acceleration testing machine. As a time indicating an insulation resistance value of not more than 10⁵Ω is measured, the films prepared in Examples 4-5 are not less than 600 hours, respectively.

### Examples 8 and 9

A cured product of an epoxy resin composition (film) according to the invention (Examples 8-9) is obtained by cutting the film prepared in Examples 4-5 into 20 cm square, sandwiching between Teflon (registered trade mark) plates, and heating at 170° C. and 5 MPa for 60 minutes with a hot plate pressing machine. With respect to the cured products of Examples 8-9, the flame retardance, thermal deterioration, glass transition temperature (Tg) and tensile elongation are measured by the following methods. The results are shown in Table 2.

(2) Flame Retardance

It is measured according to UL 94 VTM. In this case, a case that a first flame-contacting time or a second flame-contacting time is not more than 10 seconds is V-0, and a case that a first flame-contacting time or a second flame-contacting time is not more than 30 seconds is V-1.

(3) Thermal Deterioration

A time until the embrittlement of the film is measured in a hot air dryer of 120° C. The term “embrittlement” used herein means that cracking is caused when the film is bent to 180°.

(4) Glass Transition Temperature (Tg)

It is measured according to DMA measurement.

(5) Tensile Elongation

It is measured at room temperature (25° C.) with a tensilon testing machine (made by Toyo Boldwin Co., Ltd.).

TABLE 2

| | Example 8 | Example 9 |
|---|---|---|
| Flame retardance | V-1 | V-0 |
| Thermal deterioration | not less than 720 | not less than 720 |
| (hours) | | |
| Tg (° C.) | 260 | 270 |
| Tensile elongation (%) | 67 | 65 |

### Examples 10 and 11

The varnish obtained in Examples 2-3 is applied onto a polyimide film of 25 μm in thickness (Yupilex 25SGA, made by Ube Industries, Ltd.) with a roll coater so as to render a thickness of an adhesion layer after drying into 25 μm, and then a solvent is removed under drying conditions of 140° C. and 3 minutes to obtain a film (cover lay, Examples 10-11) provided with an adhesion layer (epoxy resin composition according to the invention).

### Examples 12 and 13

To an adhesion layer face of the film provided with the adhesion layer obtained in Examples 10-11 is boded a roughened face of a rolled copper foil of 18 μm in thickness (BHN foil, made by Nikko Materials Co., Ltd.), which is pressed under heating at 170° C. and 5 MPa for 60 minutes with a hot plate pressing machine to obtain a one-side copper-clad resin laminate (Examples 12-13). With respect to the one-side copper-clad resin laminates of Examples 12-13, the peeling strength between the copper foil and the resin layer is measured according to JIS C6481 with a tensilon testing machine (made by Toyo Boldwin Co., Ltd.), and as a result, the values are 10-11 N/cm.

### Examples 14 and 15

The varnish obtained in Examples 2-3 is applied onto a roughened face of a rolled copper foil of 18 μm (BHN foil, made by Nikko Materials Co., Ltd.) with a roll coater so as to render a thickness after drying into 10 μm and then a solvent is removed under drying conditions of 130° C. and 7 minutes to obtain a rolled copper foil provided with an adhesion layer. Thereafter, two rolled copper foils provided with the adhesion layer are cut out into 20 cm square, and then the adhesion layers thereof are contacted with each other and pressed under heating at 170° C. and 5 MPa for 60 minutes with a hot plate pressing machine to obtain a both-side copper-clad resin laminate (Examples 14-15). With respect to the both-side copper-clad resin laminates of Examples 14-15, the peeling strength of copper foil-adhesion layer-copper foil is measured according to JIS C6481 with a tensilon testing machine (made by Toyo Boldwin Co., Ltd.), and as a result, the values are 15-16 N/cm.

### Examples 16 and 17

The film prepared in Examples 4-5 is sandwiched between polyimide films of 25 μm in thickness (Yupilex 25SGA, made by Ube Industries, Ltd.) and pressed under heating at 170° C. and 5 MPa for 60 minutes to obtain a resin laminate (Examples 16-17). With respect to the resin laminates of Examples 16-17, the peeling strength of polyimide-adhesion layer-polyimide is measured according to JIS C6481 with a tensilon testing machine (made by Toyo Boldwin Co., Ltd.), and as a result, the values are 8-9 N/cm.

Thus, the epoxy resin composition containing the phenolic hydroxyl group-containing rubber-modified polyamide resin according to the invention is excellent in the electric characteristics as a cured product and is further sufficient to satisfy the adhesion properties, heat resistance and flame retardance for various substrates, so that it is useful in an adhesion sheet, a cover lay, a reinforcing plate, a resin laminate or the like.

1. A phenolic hydroxyl group-containing rubber-modified polyamide resin characterized by having in its molecule (a) a phenolic hydroxyl group-containing aromatic polyamide segment represented by the following formula (1): 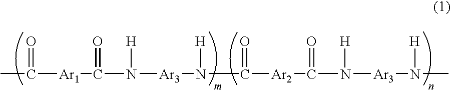
(in the formula (1), m and n are average values and satisfy a relationship of 0.005≦n/(m+n)≦1.00 and m+n is an integer of 2-200, and Ar₁ is a bivalent aromatic group, Ar₂ is a bivalent aromatic group having a phenolic hydroxyl group and Arₐ is a bivalent aromatic group) and (b) a hydrogenated butadiene polymer segment.

2. The phenolic hydroxyl group-containing rubber-modified polyamide resin according to claim 1, wherein the hydrogenated butadiene polymer segment (b) is represented by the following formula (2): 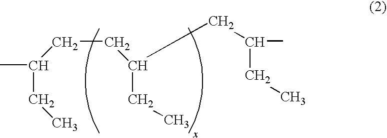
(in the formula (2), x is an average value and is an integer of 3-200).

3. The phenolic hydroxyl group-containing rubber-modified polyamide resin according to claim 1 wherein the phenolic hydroxyl group-containing aromatic polyamide segment (a) is represented by the following formula (3): 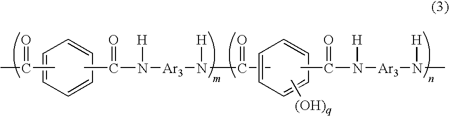
(in the formula (3), m and n are average values and satisfy a relationship of 0.005≦n/(m+n)≦1.00 and m+n is an integer of 2-200, and Ar₃ is a bivalent aromatic group and q is an average substituent number and is an integer of 1-4).

4. An epoxy resin composition comprising (A) a phenolic hydroxyl group-containing rubber-modified polyamide resin as claimed in claim 1 and (B) an epoxy resin.

5. The epoxy resin composition according to claim 4, which further contains (C) a phenolic hydroxyl group-containing polyamide resin having the phenolic hydroxyl group-containing aromatic polyamide segment (a).

6. The epoxy resin composition according to claim 4, which is shaped into a film.

7. An adhesion sheet for a flexible printed wiring board comprising an epoxy resin composition as claimed in claim 6.

8. A cured product of an epoxy resin composition formed by heat-curing an epoxy resin composition as claimed in claim 6.

9. A cured product of an adhesion sheet for a flexible printed wiring board formed by heat-curing an adhesion sheet for a flexible printed wiring board as claimed in claim 7.

10. A reinforcing plate for a flexible printed wiring board comprising a cured layer of an epoxy resin composition as claimed in claim 6.

11. A cover lay for a flexible printed wiring board comprising a cured layer of an epoxy resin composition as claimed in claim 6.

12. A metal-clad resin laminate formed by contacting at least a one-side face of a cured layer of an epoxy resin composition as claimed in claim 6 with a face selected from the group consisting of a one-side face of a metal foil layer and a resin face of a one-side metal-clad resin laminate.

13. (canceled)

14. An interlaminar insulating film characterized by using an epoxy resin composition as claimed in claim 4.

15. An epoxy resin composition comprising (A) a phenolic hydroxyl group-containing rubber-modified polyamide resin as claimed in claim 2 and (B) an epoxy resin.

16. An epoxy resin composition comprising (A) a phenolic hydroxyl group-containing rubber-modified polyamide resin as claimed in claim 3 and (B) an epoxy resin.

17. A flexible printed wiring board formed by using at least one material selected from the group consisting of
(a) an epoxy resin composition comprising a phenolic hydroxyl group-containing rubber-modified polyamide resin as claimed in claim 1 and B) an epoxy resin,
(b) an adhesion sheet for a flexible printed wiring board comprising an epoxy resin composition comprising (A) a phenolic hydroxyl group-containing rubber-modified polyamide resin as claimed in claim 1 and (B) an epoxy resin shaped into a film,
(c) a reinforcing plate for a flexible printed wiring board comprising a cured layer of an epoxy resin composition epoxy resin composition comprising (A) a phenolic hydroxyl group-containing rubber-modified polyamide resin as claimed claim 1 and (B) an epoxy resin which is shaped into a film,
(d) a cover lay for a flexible printed wiring board comprising a cured layer of an epoxy resin composition shaped into a film comprising (A) a phenolic hydroxyl group-containing rubber-modified polyamide resin as claimed in claim 1 and (B) an epoxy resin and
(e) a metal-clad resin laminate formed by contacting a one-side face or both faces of a cured layer of an epoxy resin composition comprising (A) a phenolic hydroxyl group-containing rubber-modified polyamide resin as claimed claim 1 and (B) an epoxy resin, which is shaped into a film, with a one-side face of a metal foil layer or a resin face of a one-side metal-clad resin laminate.

18. A cured product of an epoxy resin composition comprising a resin as claimed in claim 1 and an epoxy resin, which product is shaped as a film.

19. The phenolic hydroxyl group-containing rubber-modified polyamide resin according to claim 2, wherein the phenolic hydroxyl group-containing aromatic polyamide segment (a) is represented by the following formula (3): 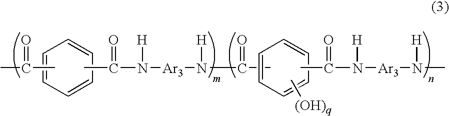
(in the formula (3), m and n are average values and satisfy a relationship of 0.005≦n/(m+n)≦1.00 and m+n is an integer of 2-200, and Ar₃ is a bivalent aromatic group and q is an average substituent number and is an integer of 1-4).

20. An epoxy resin composition comprising (A) a phenolic hydroxyl group-containing rubber-modified polyamide resin as claimed in claim 19 and (B) an epoxy resin.
